(19) United States
(12) Patent Application Publication
(10) Pub. No.: US 2023/0253251 A1
(43) Pub. Date: Aug. 10, 2023

(54) SINGULATING SEMICONDUCTOR WAFERS

(71) Applicant: Texas Instruments Incorporated, Dallas, TX (US)

(72) Inventors: Qing Ran, Chengdu (CN); Yang Liu, Chengdu (CN); Joseph O. Liu, Plano, TX (US)

(21) Appl. No.: 17/669,143

(22) Filed: Feb. 10, 2022

(51) Int. Cl. H01L 21/78; H01L 21/268

(52) U.S. Cl. CPC H01L 21/78; H01L 21/268

(57) ABSTRACT

A method of manufacturing a semiconductor package includes forming a plurality of first cuts in a semiconductor wafer. The first cuts extend through a first portion of a thickness of the semiconductor wafer and include a first set of first cuts that are parallel to one another and a second set of first cuts that are parallel to one another and perpendicular to the first set of first cuts. In addition, the method includes forming a plurality of second cuts in the wafer after forming the first cuts. The second cuts are vertically aligned with the first cuts and extend through a second portion of the thickness of the semiconductor wafer. The second cuts include a first set of second cuts that are parallel to one another and a second set of second cuts that are parallel to one another and perpendicular to the first set of second cuts

### BACKGROUND

During semiconductor chip manufacturing, circuits may be formed on a semiconductor wafer (or more simply “wafer”). The wafer may be separated (or “singulated”) into a plurality of semiconductor dies, each die having a circuit formed thereon. Each die is then processed to form a semiconductor package that may be integrated with an electronic device (e.g., computers, smartphones).

### SUMMARY

Some examples described herein are directed to a method of manufacturing a semiconductor package. In some examples, the method includes forming a plurality of first cuts in a semiconductor wafer, wherein the plurality of first cuts extend through a first portion of a thickness of the semiconductor wafer. The plurality of first cuts includes a first set of first cuts that are parallel to one another, and a second set of first cuts that are parallel to one another and perpendicular to the first set of first cuts. In addition, the method includes forming a plurality of second cuts in the semiconductor wafer after forming the plurality of first cuts, wherein the plurality of second cuts are vertically aligned with the plurality of first cuts and extend through a second portion of the thickness of the semiconductor wafer. The plurality of second cuts includes a first set of second cuts that are parallel to one another, and a second set of second cuts that are parallel to one another and perpendicular to the first set of second cuts.

In some examples, the method includes directing a laser into a semiconductor wafer, wherein the semiconductor wafer comprises a plurality of circuits and a plurality of scribe streets positioned between the circuits. In addition, the method includes forming a plurality of first cuts with the laser through a first portion of a thickness of the semiconductor wafer that are vertically aligned with the scribe streets. Further, the method includes, after forming the plurality of first cuts, forming a plurality of second cuts with the laser through a second portion of the thickness of the semiconductor wafer that are vertically aligned with the plurality of first cuts.

In some examples, the method includes emitting an infrared laser from a laser cutter at a power level between 0.5 Watts (W) and 0.7 W. In addition, the method includes forming a plurality of first cuts in a semiconductor wafer with the laser, wherein the plurality of first cuts extend through a first portion of a thickness of the semiconductor wafer. Further, the method includes forming a plurality of second cuts in the semiconductor wafer with the laser after forming the plurality of first cuts, wherein the plurality of second cuts are aligned with the plurality of first cuts and extend through a second portion of the thickness of the semiconductor wafer.

### BRIEF DESCRIPTION OF THE DRAWINGS

For a detailed description of various examples, reference will now be made to the accompanying drawings in which:

FIG. 1A is a top view of a semiconductor wafer that is to be singulated.

FIG. 1B is a cross-sectional view of the semiconductor wafer of FIG. 1A, taken along section 1B-1B in FIG. 1A.

FIGS. 2A and 2B are cross-sectional views of a method for singulating a semiconductor wafer.

FIGS. 3A and 3B are top views of a process flow for forming a first set of a plurality of first cuts in a semiconductor wafer according to some examples.

FIG. 3C is a perspective view of a semiconductor wafer showing the first set of the plurality of first cuts of FIGS. 3A and 3B according to some examples.

FIGS. 3D and 3E are top views of a process flow for forming a second set of a plurality of first cuts in a semiconductor wafer according to some examples.

FIG. 3F is a perspective view of a semiconductor wafer showing the second set of the plurality of first cuts of FIGS. 3D and 3E along with the first set of the plurality of first cuts of FIGS. 3A and 3B according to some examples.

FIG. 3G is a perspective view of a semiconductor wafer showing the plurality of first cuts and a first set of a plurality of second cuts according to some examples.

FIG. 3H is a perspective view of a semiconductor wafer showing the plurality of first cuts, the first set of the plurality of second cuts of FIG. 3G, and a second set of the plurality of second cuts according to some examples.

FIG. 4 is a block diagram of a method for singulating a semiconductor wafer according to some examples.

FIGS. 5A-5E are sequential cross-sectional views depicting a process flow for singulating a semiconductor wafer according to some examples.

FIGS. 6A-6C are sequential cross-sectional views depicting a process flow for singulating a semiconductor wafer according to some examples.

FIGS. 7A-7C are sequential cross-sectional views depicting a process flow for singulating a semiconductor wafer according to some examples.

FIG. 8 is a perspective view of a semiconductor die that was singulated from a semiconductor wafer according to some examples.

FIGS. 9A-9D are sequential cross-sectional views depicting a process flow for manufacturing a semiconductor package using a semiconductor die that was singulated from a semiconductor wafer according to some examples.

FIG. 10 is a block diagram of a method for manufacturing a semiconductor package using a semiconductor die that was singulated from a semiconductor wafer according to some examples.

### DETAILED DESCRIPTION

A semiconductor wafer may be singulated into a plurality of semiconductor dies using a cutting implement such as a saw or laser. In some circumstances, an initial cut is made part way through the wafer, and then internal stresses within the wafer may propagate a crack from the initial cut through the wafer. However, as successive cuts are made in the wafer, the internal stresses within the wafer may become non-uniformly distributed such that a crack may meander away from the intended cut line. Such crack meandering may be more greatly pronounced at the intersection of other cut lines along the wafer. If a crack meanders too far from an intended cut line, the wafer may be rendered totally or partially defective.

Accordingly, examples disclosed herein include methods for singulating a semiconductor wafer that balance internal stresses of the wafer and thereby increase an accuracy for cut lines formed in the wafer. In some examples, the method may include forming a plurality of first cut lines through a first portion of the wafer thickness, while leaving a remaining thickness of the wafer uncut. Thereafter, the method may include forming a plurality of second cut lines that are vertically aligned with the plurality of first cut lines that extend through a second portion of the wafer thickness. By forming cut lines in the wafer in this manner, the uncut portions of the wafer thickness (which extend across an entire surface area of the wafer) allow the internal stresses within the wafer to be more evenly distributed throughout the singulation process. Accordingly, any cracks that propagate from the cut lines (e.g., the plurality of first cut lines, the plurality of second cut lines) may not meander within the wafer. In addition, in some examples, the parameters of the cutting implement (e.g., a laser cutter) may also be adjusted to reduce or even prevent crack meandering within the wafer outside of the scribe streets during the above-described process. Therefore, using the methods disclosed herein, manufacturing defects resulting from singulation of semiconductor dies may be reduced.

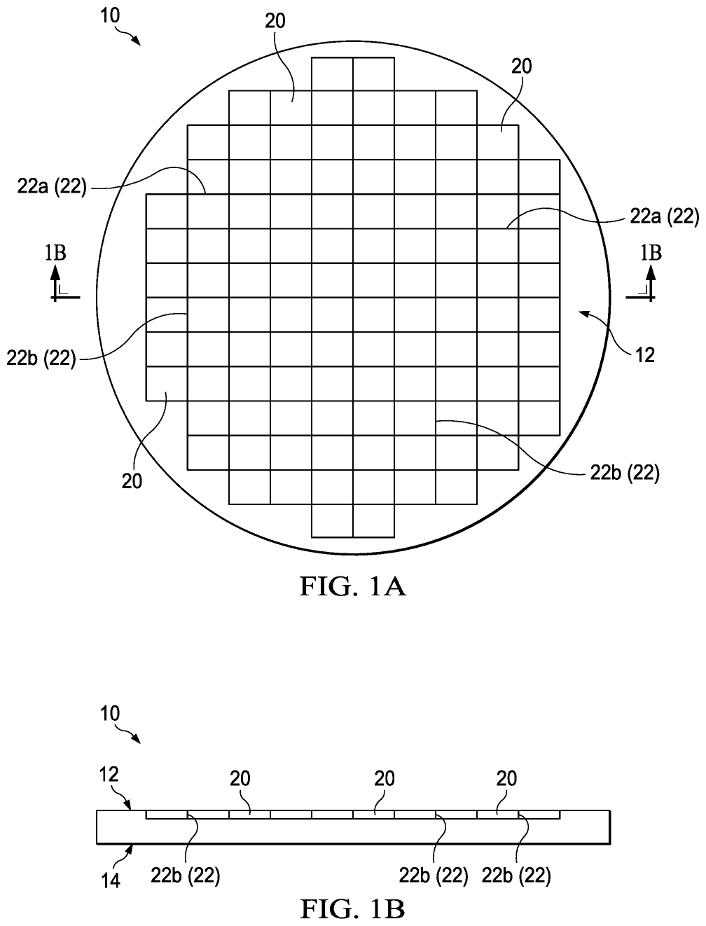

Referring now to FIGS. 1A and 1B, a semiconductor wafer 10 is shown. Semiconductor wafer 10 (or more simply “wafer 10”) may comprise a disc of semiconductor material, such as silicon, that includes a first or device side 12 and a second or non-device side 14 opposite the device side 12. The device side 12 may comprise a plurality of circuits 20 formed thereon. Each circuit 20 may comprise a single circuit or a plurality of circuits 20. The circuits 20 may be arranged in a grid pattern comprising columns and rows of circuits 20 that are arranged side-by-side along device side 12. The circuits 20 may be separated by a plurality of gaps or “scribe streets” 22 that generally extend in straight lines across device side 12. Specifically, the scribe streets 22 may comprise a plurality of first scribe streets 22a, and a plurality of second scribe streets 22b. The plurality of first scribe streets 22a may be parallel to one another, the plurality of second scribe streets 22b may be parallel to one another, and the plurality of first scribe streets 22a may be perpendicular to the plurality of second scribe streets 22b.

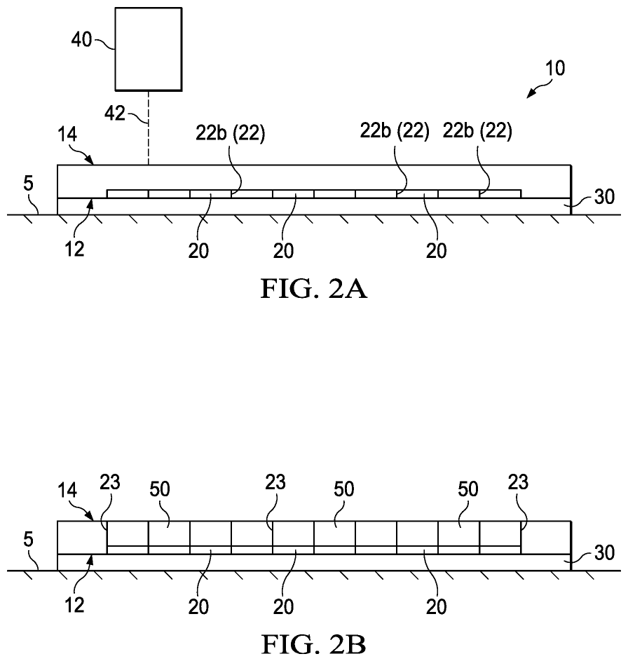

Referring now to FIGS. 2A and 2B, a side schematic view of a singulation process for wafer 10 is shown. In particular, wafer 10 may be singulated using a laser cutter 40 that emits a laser 42 for cutting wafer 10 along scribe streets 22 (including the plurality of first scribe streets 22a and the plurality of second scribe streets 22b). Initially, a layer of tape 30 may be applied to one side of the wafer 10. As shown in FIGS. 2A and 2B, the tape 30 may be applied to the device side 12. However, tape 30 may be applied to non-device side 14.

Next, the wafer 10 may be placed on a table 5 such that the tape 30 is positioned between the wafer 10 and table 5. Thereafter, as shown in FIG. 2B, the table 5 and/or the laser cutter 40 may be moved so as to pass the laser 42 along the scribe streets 22 (including the plurality of first scribe streets 22a and the plurality of second scribe streets 22b) to form cuts 23 through wafer 10 and thereby define a plurality of semiconductor dies 50. During this process, the tape 30 may remain un-cut so that the separated semiconductor dies 50 are retained in place. Following singulation, the semiconductor dies 50 may be subjected to further processing to thereby form a semiconductor package that may be utilized within an electronic device as previously described.

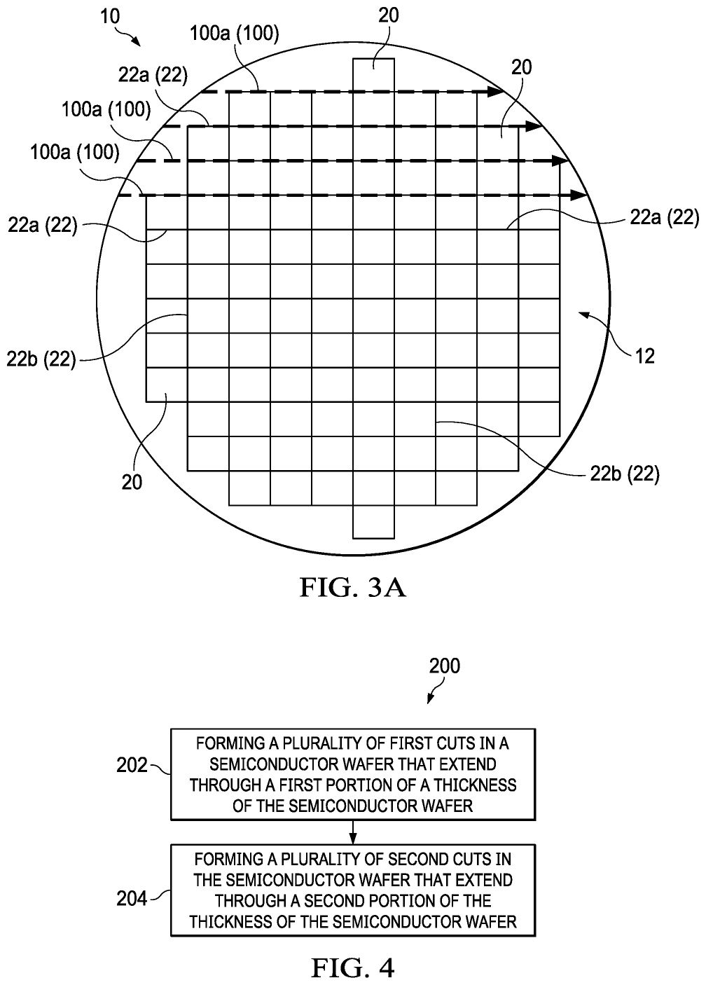

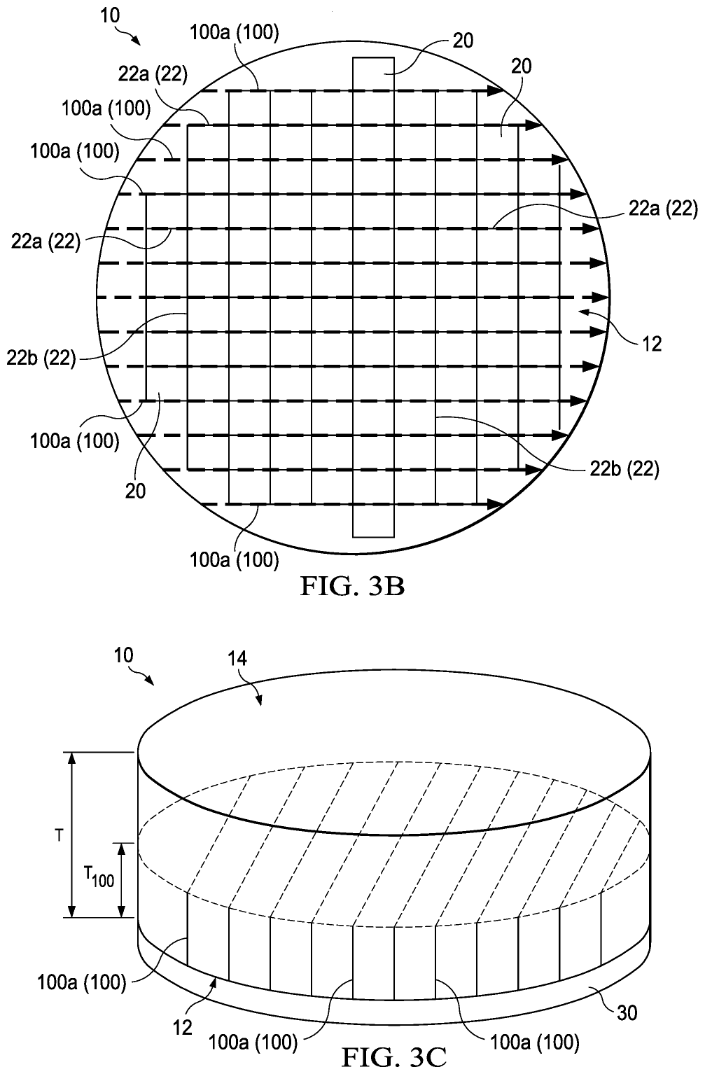

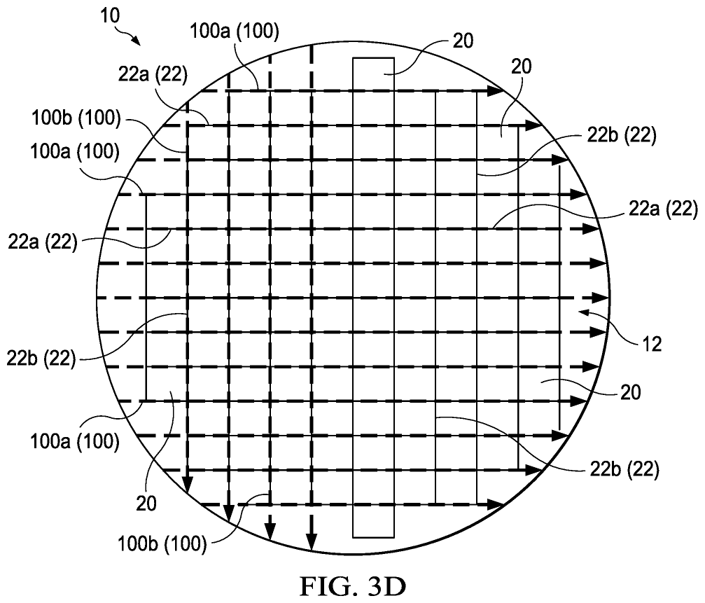

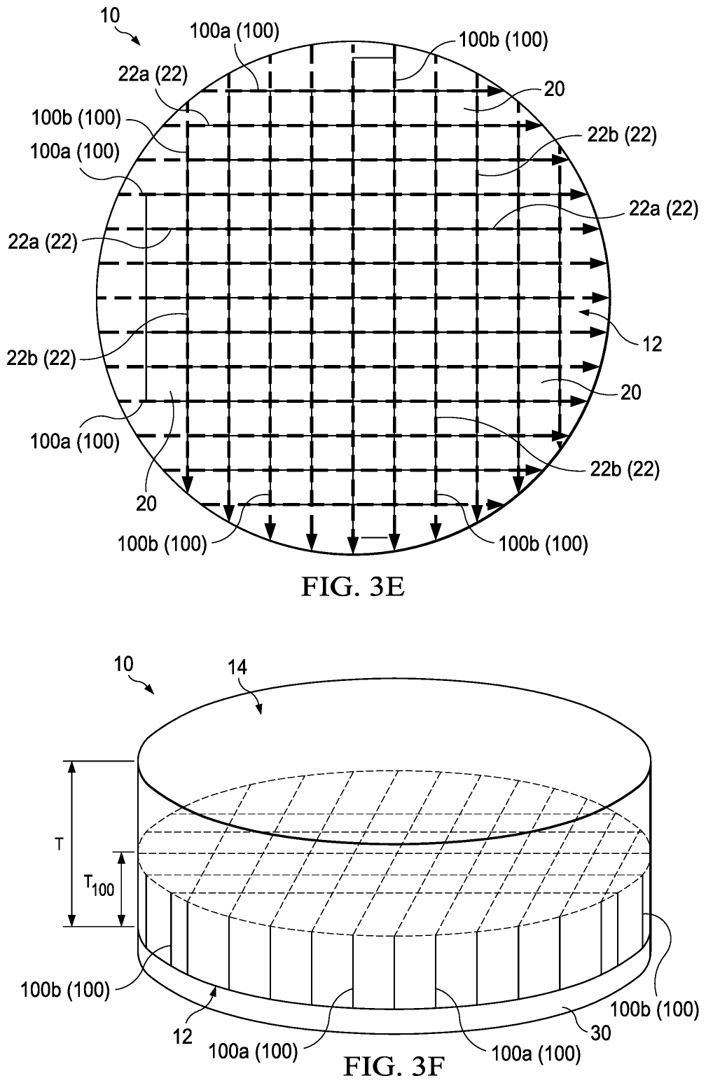

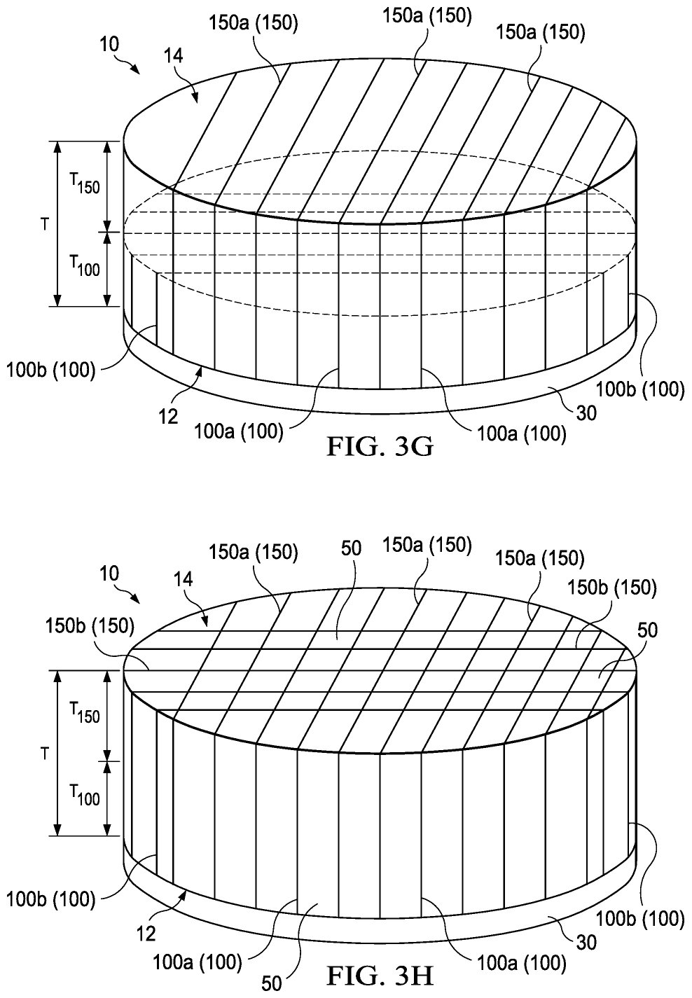

FIGS. 3A-3H illustrate a process flow for singulating a semiconductor wafer (e.g., wafer 10) according to some examples. In addition, FIG. 4 is a flow diagram of a method 200 for singulating a semiconductor wafer according to some examples. Accordingly, FIGS. 3A-3H and 4 are described in parallel.

Initially, method 200 includes forming a plurality of first cuts in a semiconductor wafer that extend through a first portion of a thickness of the semiconductor wafer at block 202. For instance, as shown in FIGS. 3A-3F, a plurality of first cuts 100 may be formed in wafer 10 that extend through a first portion T₁₀₀ of a thickness T (FIGS. 3C and 3F) of wafer 10. The thickness T may extend from the device side 12 to the non-device side 14. In some examples, the plurality of first cuts 100 may extend from the device side 12 through the first portion T₁₀₀ of thickness T. In addition, the plurality of first cuts 100 may be formed in wafer 10 using a laser cutter (e.g., laser cutter 40 in FIGS. 2A and 2B). In particular, as the laser is traversed across wafer 10 to form the plurality of first cuts 100, a laser cutter may remove (e.g., melt, vaporize) material of the semiconductor wafer 10 and cracks may propagate from the areas where material was removed to form the plurality of first cuts 100.

More specifically, the plurality of first cuts 100 may be formed in wafer 10 by forming a first set of first cuts 100a that are vertically aligned with the first scribe streets 22a (FIGS. 3A-3C), and forming a second set of first cuts 100b that are vertically aligned with the second scribe streets 22b (FIGS. 3D-3F). As previously described, the plurality of first cuts 100 (which includes the first set of first cuts 100a and the second set of first cuts 100b) each extend through the first portion T₁₀₀ of thickness T as shown in FIGS. 3C and 3F. As a result, after forming the plurality of first cuts 100 in wafer 10, the remaining portion of the thickness T (that is, the portion of the thickness T that does not include the first portion T₁₀₀) may remain uncut and whole. Accordingly, without being limited to this or any other theory, while the plurality of first cuts 100 may form stress risers within the wafer 10, the internal stresses within the wafer 10 may be more uniformly and evenly distributed throughout the uncut portion of the thickness T so that any cracks that may propagate from the plurality of first cuts 100 do not meander away from the intended cut lines vertically aligned with scribe streets 22.

Referring again to FIG. 4, after block 202, method 200 includes forming a plurality of second cuts in the semiconductor wafer that extend through a second portion of the thickness of the semiconductor wafer at block 204. For instance, referring now to FIGS. 3G and 3H, forming the plurality of second cuts 150 may comprise forming a first set of second cuts 150a in the wafer 10 that are vertically aligned with the first set of first cuts 100a and forming a second set of second cuts 150b in the wafer 10 that are vertically aligned with the second set of first cuts 100b. Together, the first set of second cuts 150a and the second set of second cuts 150b may comprise the plurality of second cuts 150. In addition, because the first set of second cuts 150a is vertically aligned with the first set of first cuts 100a and the second set of second cuts 150b is vertically aligned with the second set of first cuts 100b, the first set of second cuts 150a may be vertically aligned with the first scribe streets 22a and the second set of second cuts 150b may be vertically aligned with the second scribe streets 22b (FIG. 1A). In addition, as with the plurality of first cuts 100, the plurality of second cuts 150 may be formed in wafer 10 using a laser cutter (e.g., laser cutter 40 in FIGS. 2A and 2B). In particular, as the laser is traversed across wafer 10 to form the plurality of first cuts 150, a laser cutter may remove (e.g., melt, vaporize) material of the semiconductor wafer 10 and cracks may propagate from the areas where material was removed to form the plurality of first cuts 150.

Referring still to FIGS. 3G and 3H, the plurality of second cuts 150 (including the first set of second cuts 150a and the second set of second cuts 150b) may extend through a second portion T₁₅₀ of the thickness T. In some examples, the second portion T₁₅₀ may extend the remaining portion of the thickness T from the first portion T₁₀₀ to the non-device side 14. Specifically, in some examples, the first portion T₁₀₀ and the second portion T₁₅₀ may each comprise approximately half (e.g., 50%) of the thickness T, so that the plurality of first cuts 100 may extend from the device side 12, along the scribe streets 22, and the plurality of second cuts 150 may extend from the plurality of first cuts 100 to the non-device side 14 to thereby complete the singulation process and transform the wafer 10 into the plurality of semiconductor dies 50 (FIG. 3H).

As previously described, the plurality of first scribe streets 22a may be parallel to one another, the plurality of second scribe streets 22b may be parallel to one another, and the plurality of first scribe streets 22a may be perpendicular to the plurality of second scribe streets 22b. In addition, as is also previously described, the plurality of first cuts 100 may be vertically aligned with the scribe streets 22 (with the first set of first cuts 100a being vertically aligned with the plurality of first scribe streets 22a and the second set of first cuts 100b being vertically aligned with the plurality of second scribe streets 22b), and the plurality of second cuts 150 may be vertically aligned with the plurality of first cuts 100 and the scribe streets 22 (with the first set of second cuts 150a being vertically aligned with the first set of first cuts 100a and the plurality of first scribe streets 22a, and the second set of second cuts 150b being vertically aligned with the second set of first cuts 100b and the plurality of second scribe streets 22b). As a result, for the plurality of first cuts 100, the first set of first cuts 100a may be parallel to one another, the second set of first cuts 100b may be parallel to one another, and the first set of first cuts 100a may be perpendicular to the second set of first cuts 100b. Likewise, for the plurality of second cuts 150, the first set of second cuts 150a may be parallel to one another, the second set of second cuts 150b may be parallel to one another, and the first set of second cuts 150a may be perpendicular to the second set of second cuts 150b.

As shown in FIG. 3H, the singulated semiconductor dies 50 may be held together by tape 30 as previously described. Accordingly, following singulation, the semiconductor dies 50 may be separated from tape 30 and subjected to further processing to form semiconductor packages (described in more detail below).

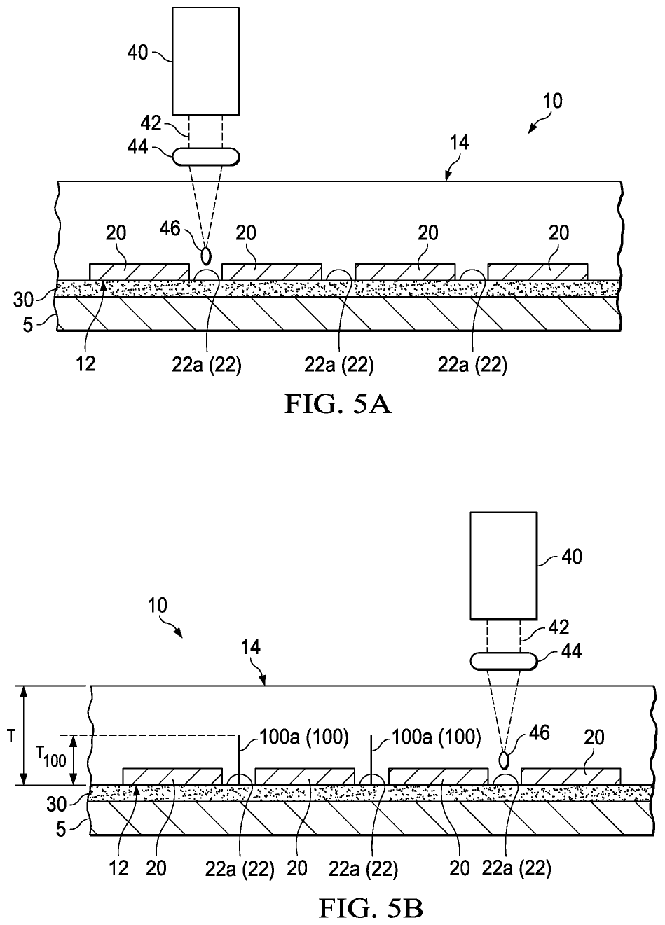

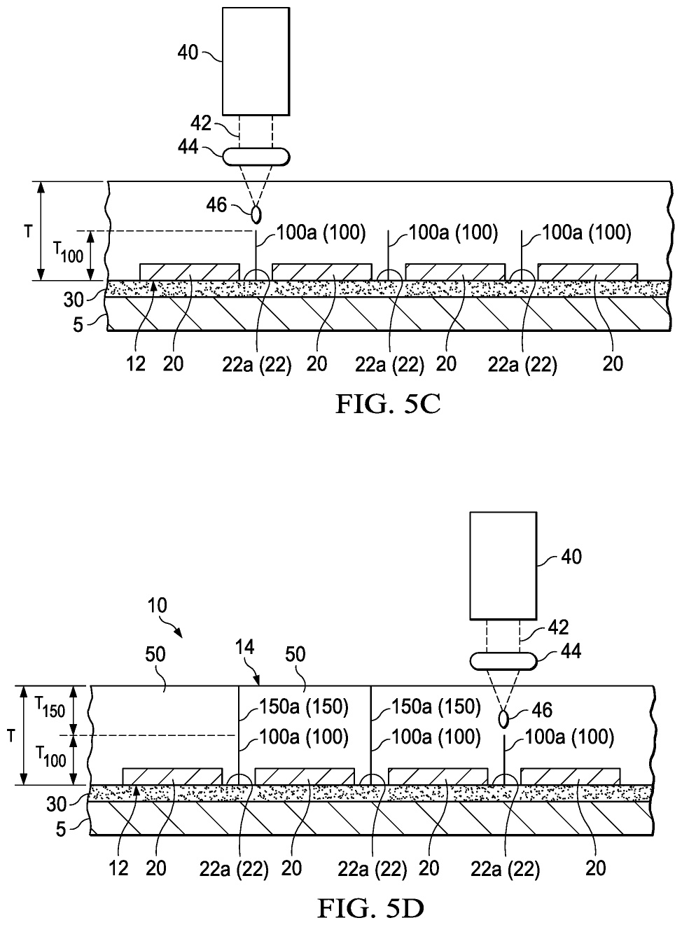

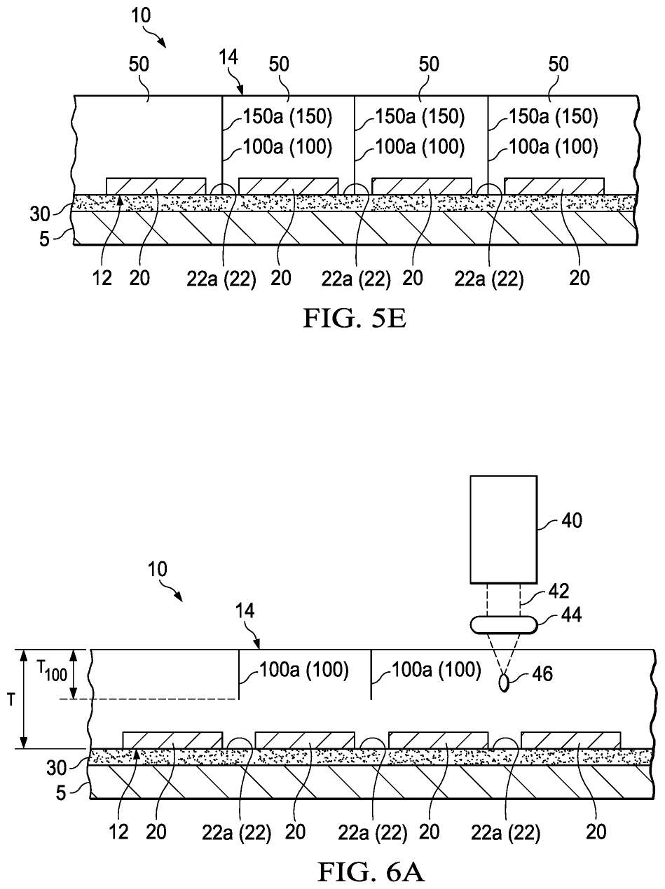

As previously described, in some examples, a singulation process may comprise forming a plurality of first cuts 100 (e.g., including a first set of first cuts 100a and a second set of first cuts 100b as shown in FIGS. 3A-3F) through a first portion T₁₀₀ of thickness T of the semiconductor wafer 10 and then forming a plurality second of cuts 150 (e.g., including a first set of second cuts 150a and a second set of second cuts 150b as shown in FIGS. 3G and 3H) through a second portion T₁₅₀ of the thickness T of the wafer 10. As shown in FIGS. 5A-5E, the plurality of first cuts 100 and the plurality of second cuts 150 may be formed in wafer 10 using laser cutter 40.

More specifically, laser cutter 40 may emit laser 42 which in some examples may comprise an infrared (IR) laser, that is directed toward wafer 10 to form the plurality of first cuts 100 and the plurality of second cuts 150. In some examples, the laser 42 may be focused into a focal area 46 by a focusing assembly 44. The focal area 46 may represent a region or volume of space in which the laser 42 is sufficiently concentrated to fracture or remove (e.g., melt, vaporize) the material of wafer 10.

Cracks may propagate from the areas or regions of removed material to thereby complete the formation of the cut (e.g., the plurality of first cuts 100 and the plurality of second cuts 150). However, because internal stresses within the wafer 10 are more uniformly and evenly distributed throughout the uncut portion of the semiconductor wafer 10, the propagated cracks may be aligned with the scribe streets 22 as described above. Specifically, a crack that propagates from the areas or regions of material removed via laser 42 using the examples described herein are contained within the scribe street 22 and do not traverse within 5 μm of scribe seals that surround each circuits 20.

The scribe seals (not shown) may comprise a plurality of stacked layers (e.g., metallic layers) that are embedded within the wafer 10, to prevent cracks from propagating under the circuits 20 during singulation. In some examples, when the scribe streets 22 are 37 μm wide (e.g., extending between the scribe seals of adjacent circuits 20 positioned on wafer 10), the cracks that propagate from the areas or regions of material via removed laser 42 using the examples described herein do not meander more than 13.5 μm laterally along the surface of the wafer 10. In these examples, a deviation larger than 13.5 μm will place the cracks too close to the scribe seals such that the resulting semiconductor die may be rendered defective.

The focusing assembly 44 may comprise a lens or multiple lenses in some examples. As shown in FIGS. 5A-5D, the laser 42 may pass through wafer 10 from non-device side 14 without damaging (e.g., melting, vaporizing) the material forming wafer 10 (e.g., semiconductor material such as silicon) until reaching the focal area 46 positioned within the wafer 10. Within the focal area 46, the wafer 10 may be removed (e.g., melted, vaporized) by laser 42 so that a cut (e.g., one of the plurality of first cuts 100 or the plurality of second cuts 150) is formed.

Thus, as shown in FIGS. 5A and 5B, some examples of a singulation process described herein may include maneuvering the laser cutter 40, the laser 42, the wafer 10, and/or the table 5 to traverse the focal area 46 of laser 42 through the wafer 10 along paths that are vertically aligned with the scribe streets 22 (e.g., including the plurality of first scribe streets 22a and the plurality of second scribe streets 22b shown in FIG. 1A) to form the plurality of first cuts 100. During this process, the focal area 46 may be placed at a depth within wafer 10 that is at or proximate the device side 12 (e.g., so that the depth of focal area 46 within wafer 10 when forming the plurality of first cuts 100 is more proximate the device side 12 than the non-device side 14). Accordingly, as the focal area 46 of laser 42 is traversed along paths that are vertically aligned with the scribe streets 22, the material of wafer 10 that is within and/or proximate to focal area 46 may be removed (e.g., melted, vaporized) to form the plurality of first cuts 100 (including the first set of first cuts 100a and the second set of first cuts 100b shown in FIGS. 3C and 3F).

Likewise, referring to FIGS. 5C and 5D, following formation of the plurality of first cuts 100, the laser 42 may be adjusted and then again traversed across the wafer 10 to form the plurality of second cuts 150 (e.g., including the first set of second cuts 150a and the second set of second cuts 150b shown in FIGS. 3G and 3H). In particular, when forming the plurality of second cuts 150, the focal area 46 may be adjusted (e.g., by adjusting or changing the focusing assembly 44, adjusting a position and/or angle of the laser 42) so that the focal area 46 is placed at a depth within wafer 10 that is more proximate the non-device side 14 than the plurality of first cuts 100. In some examples, when forming the plurality of second cuts 150, the focal area 46 may be placed at a depth within wafer 10 that is more proximate non-device side 14 than device side 12. Accordingly, as the focal area 46 of laser 42 is traversed along paths that are vertically aligned with the scribe streets 22 and the plurality of first cuts 100, the material of wafer 10 that is within and/or proximate to focal area 46 may be removed (e.g., melted, vaporized) to form the plurality of second cuts 150 (including the first set of second cuts 150a, and the second set of second cuts 150b).

Referring now to FIG. 5E, in some examples, the plurality of first cuts 100 and the plurality of second cuts 150 may align with one another to form a complete cut (e.g., cuts 23 in FIG. 2B) through the thickness T of wafer 10. As a result, following formation of the plurality of first cuts 100 and the plurality of second cuts 150 as previously described, the wafer 10 may be singulated into the plurality of semiconductor dies 50—each having a corresponding one of the circuits 20 formed thereon.

As previously described, during the singulation process, the tape 30 may remain uncut so that the semiconductor dies 50 may be retained in place. In some examples, the focal area 46 of laser 42 may be arranged and configured so that tape 30 is unaffected (or substantially unaffected) as the focal area 46 is traversed through the wafer 10 as previously described. In addition, in some examples, metallic materials may be positioned along the device side 12 (e.g., metallic materials associated with circuits 20 or other devices and/or structures). In some examples, the metallic materials may extend across or over scribe streets 22 and may inhibit further progression of laser 42 therethrough to cut or damage tape 30.

In some examples, the power level of the laser 42, which may comprise the output power level of laser cutter 40, is adjusted to 0.5 Watts (W) to 0.7 W to form the plurality of first cuts 100 and the plurality of second cuts 150, and to also prevent (or at least reduce) cracks that are initiated from the plurality of first cuts 100 from propagating through the entire thickness of the wafer 10. Specifically, a power level of laser 42 that is below 0.5 W will not allow a sufficient amount of the material of wafer 10 to be removed (e.g., melted, vaporized) so as to form the plurality of first cuts 100 and the plurality of second cuts 150 along the first portion T₁₀₀ and second portion T₁₅₀, respectively, of thickness T. Conversely, a power level of laser 42 that is above 0.7 W will import a sufficiently high level of energy into the material of wafer 10 to initiate large cracks from the plurality of first cuts 100 that may extend through the entire thickness T. These large cracks may meander (e.g., laterally) within wafer 10 away from the intended cut lines vertically aligned with scribe streets 22 and could therefore cause some or all of the wafer 10 to become defective as previously described.

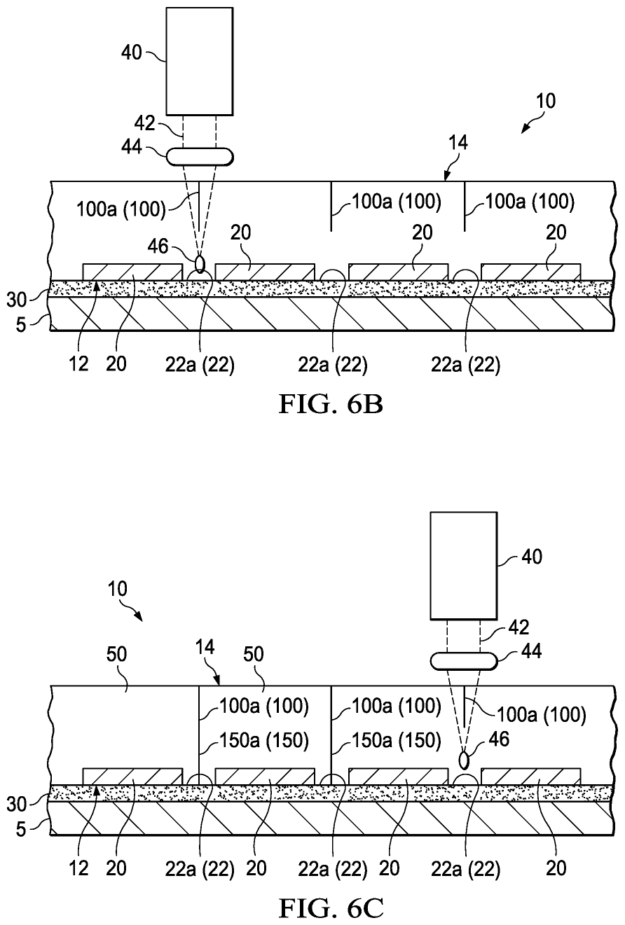

In some examples, the plurality of first cuts 100 may extend from the non-device side 14 of wafer 10 (as opposed to device side 12 as previously described). For instance, as shown in FIGS. 6A-6C, the plurality of first cuts 100 may initially be formed by laser cutter 40 so that the plurality of first cuts 100 extend through the first portion T₁₀₀ of thickness T from non-device side 14. Specifically, the laser 42 may be adjusted (e.g., via focusing assembly 44 or movement of the laser cutter 40 as previously described) such that focal area 46 is positioned more proximate non-device side 14 than device side 12, and then the focal area 46 may be traversed across the wafer 10 to form the plurality of first cuts 100 at or proximate to non-device side 14. Thereafter, the laser 42 may be adjusted so that the focal area 46 is placed at a depth that is more proximate device side 12 than the plurality of first cuts 100, and then the focal area 46 of laser 42 is traversed across the wafer 10 to form the plurality of second cuts 150 through the second portion T₁₅₀ of thickness T that extends from the plurality of first cuts 100 to the device side 12.

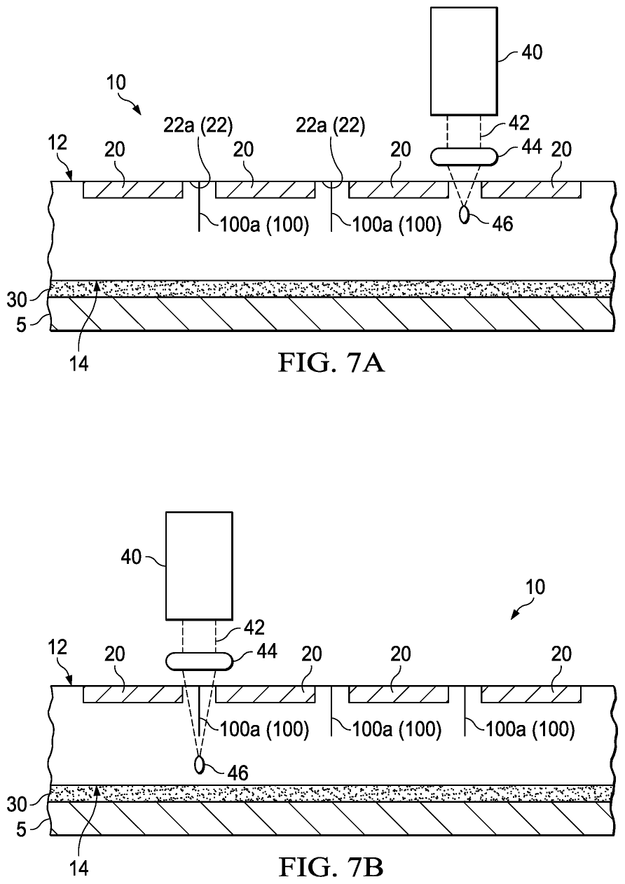

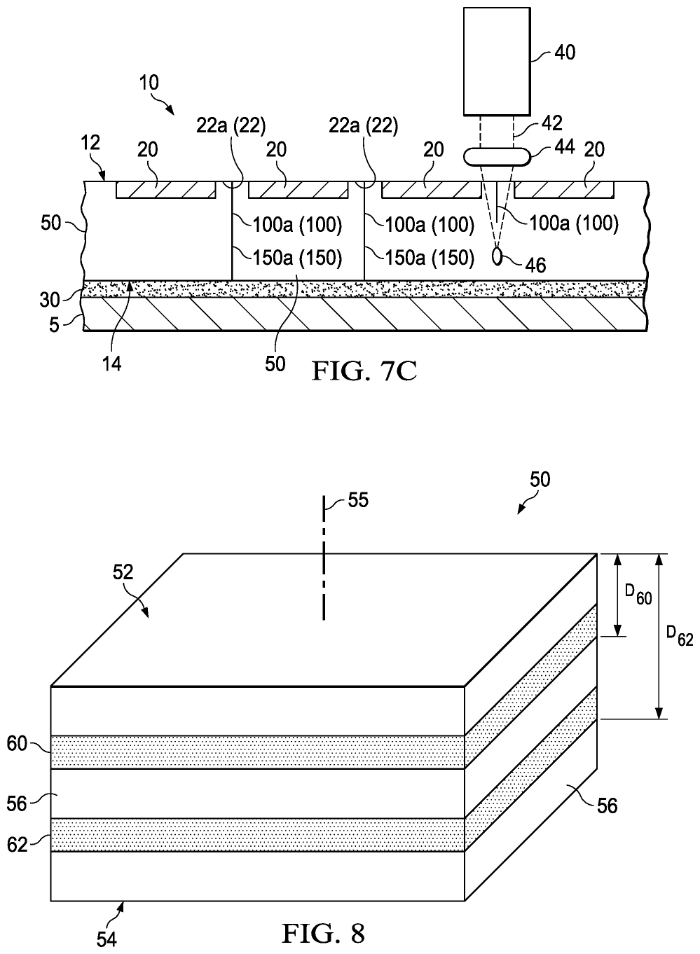

In some examples, the tape 30 may be placed along non-device side 14 such that device side 12 faces toward laser cutter 40. For instance, as shown in FIGS. 7A-7C, in some examples, tape 30 is attached to non-device side 14 so that tape 30 is engaged between non-device side 14 and table 5 during operations. As a result, device side 12 (including circuits 20) may face upward, toward laser cutter 40 such that laser 42 extends into wafer 10 from device side 12 (as opposed to non-device side 14). During operations, the plurality of first cuts 100 may extend through the first portion T₁₀₀ of thickness T from either device side 12 or non-device side 14 as previously described. In the example of FIGS. 7A-7C, the plurality of first cuts 100 may extend from or at proximate to device side 12, and then the plurality of second cuts 150 may extend from the plurality of first cuts 100 through the second portion T₁₅₀ of thickness T to the non-device side 14.

Referring now to FIG. 8, a perspective view of a semiconductor die 50 that was singulated from wafer 10 using the methods described herein is shown. The semiconductor die 50 has a first or device side 52, a second or non-device side 54 opposite the device side 52, and a central axis 55 that extends perpendicularly through the device die 52 and non-device side 54. The device side 52 may correspond with the device side 12 of wafer 10 (FIGS. 1A and 1B), and the non-device side 54 may correspond with the non-device side 14 of wafer 10 (FIGS. 1A and 1B). In addition, the semiconductor die 50 includes a plurality of side surfaces 56 that extend generally axially (with respect to axis 55) between the device side 52 and non-device side 54. The side surfaces 56 may together define an outer perimeter of the semiconductor die 50.

As described above, the semiconductor die 50 is singulated or cut from the wafer 10 with a laser cutter 40 via a first plurality of cuts 100 and a plurality of second cuts 150 (FIGS. 5A-5E, 6A-6C, and 7A-7C). The plurality of first cuts 100 and the plurality of second cuts 150 (FIGS. 5A-5E, 6A-6C, and 7A-7C) may form the side surfaces 56 of the semiconductor die 50. During the singulation process, the focal area (e.g. focal area 46) may be placed within the semiconductor material of wafer 10 to remove (e.g., melt, vaporize) material as described above, and the regions along the side surfaces 56 semiconductor die 50 where the laser focal area was located during this process comprise a pattern of discontinuities resulting from the interaction of the laser (e.g., laser 42) and the semiconductor material of wafer 10. In particular, the laser may melt, vaporize, or otherwise remove material to form layers of polysilicon within wafer 10 when making the plurality of first cuts 100 and the plurality of second cuts 150, so that the resulting semiconductor dies 50 may have layers of discontinuities along the side surfaces 56.

More specifically, as shown in FIG. 8, the side surfaces 56 of semiconductor die 50 may comprise a first discontinuity layer 60 and a second discontinuity layer 62 spaced from the first discontinuity layer 60 along axis 55. In some examples, the first discontinuity layer 60 and the second discontinuity layer 62 may be referred to as a “first layer of discontinuities” and a “second layer of discontinuities,” respectively. The first discontinuity layer 60 may be positioned axially between the device side 52 and the second discontinuity layer 62, with respect to axis 55. In addition, the second discontinuity layer 62 may be axially positioned between the first discontinuity layer 60 and the non-device side 54, with respect to axis 55. As previously described above, the first discontinuity layer 60 and the second discontinuity layer 62 may correspond and align with the path that the laser (e.g., laser 42 in FIGS. 5A-5E, 6A-6C, and 7A-7C) took through wafer 10 when forming the plurality of first cuts 100 and the plurality of second cuts 150. The layers of side surfaces 56 that are positioned axially adjacent the first discontinuity layer 60 and second discontinuity layer 62 (including axially between the first discontinuity layer 60 and second discontinuity layer 62) may correspond with regions within semiconductor wafer 10 where cracks propagated from the regions that were removed (e.g., melted, vaporized) by laser 42 as described above. Thus, these regions that are axially adjacent the first discontinuity layer 60 and the second discontinuity layer 62 are smoother (e.g., have a lower surface roughness) than the first discontinuity layer 60 and second discontinuity layer 62.

In some examples, the depth of the first discontinuity layer 60 and the depth of the second discontinuity layer 62 may be selected to ensure that cracks that propagate from the regions of removed material do not meander away from the intended cut line (e.g., within and along the scribe streets 22). In some examples, a total thickness of the semiconductor die 50 is be 279 μm, and the depth D60 of first discontinuity layer 60 from device side 52 is 34 μm and the depth D62 of the second discontinuity layer 62 from device side is 211 μm (that is, the first discontinuity layer 60 and the second discontinuity layer 62 may extend to a lower-most depths within the semiconductor wafer 10 of 34 μm and 211 μm, respectively).

In some examples, a singulation process according to examples described herein may comprise performing four different cuts through the total thickness of the semiconductor wafer 10, so that there is a total four discontinuity layers that are spaced along the thickness of the semiconductor wafer 10. In some examples, the total thickness of the semiconductor wafer 10 is 254 μm, the first discontinuity layer extends to a depth of 60 μm from the non-device side 14, the second discontinuity layer extends to a depth of 108 μm from the non-device side 14, the third discontinuity layer extends to a depth of 172 μm from the non-device side 14, and the fourth discontinuity layer extends to a depth of 220 μm from the non-device side 14. In addition in these examples, the fourth discontinuity layer is also spaced 34 μm from the device side 12 of semiconductor wafer 10.

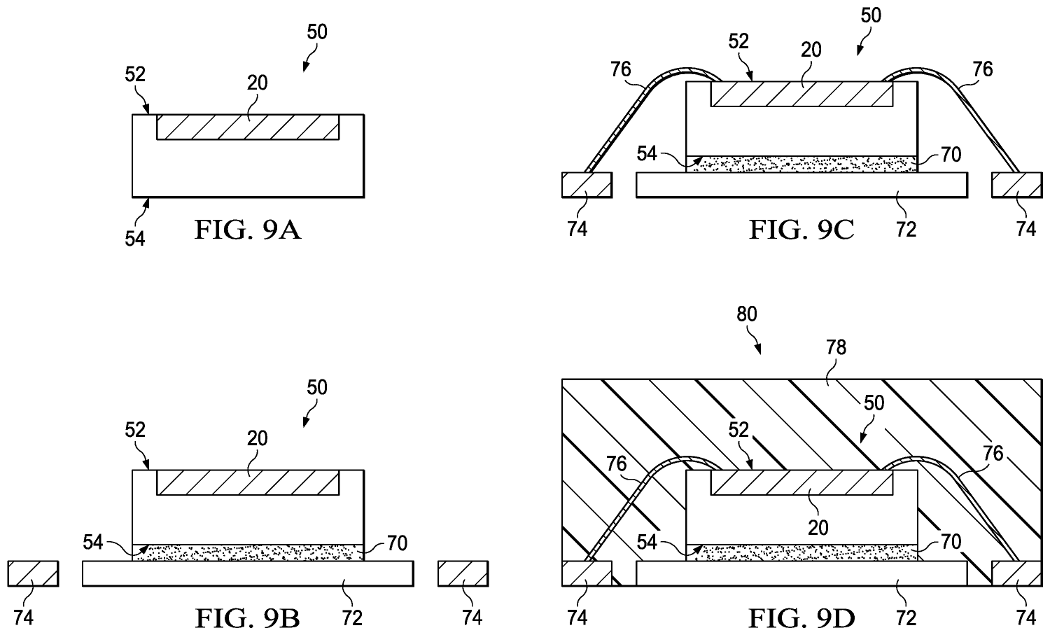

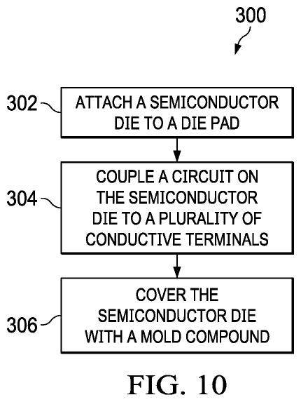

FIGS. 9A-9D illustrate a process flow for manufacturing a semiconductor package using a semiconductor die that was singulated from a wafer (e.g., wafer 10) using the examples described herein. In addition, FIG. 10 is a flow diagram of a method 300 for manufacturing a semiconductor package using a semiconductor die that was singulated from a wafer (e.g., wafer 10) using the examples described herein. Accordingly, FIGS. 9A-9D and 10 are described in parallel.

Initially, the method 300 of FIG. 10 includes attaching a semiconductor die to a die pad at block 302. For instance, as shown in FIGS. 9A and 9B, the semiconductor die 50 may be produced via a singulation process for a semiconductor wafer (e.g., wafer 10) according to the examples described herein. Thus, a method for manufacturing a semiconductor die may comprise a combination of a method for singulating the semiconductor die according to the examples described above and the methods of manufacturing shown and described in FIGS. 9A-9D and 10. The semiconductor die 50 may be similar to the semiconductor die 50 described above and shown in FIG. 8. Thus, the semiconductor die 50 may have a device side 52, a non-device side 54 opposite the device side 52, and a circuit 20 positioned on the device side 52. The non-device side 54 maybe secured to a die pad 72 via a die attach layer 70 (e.g., solder paste). The die pad 72 may be coupled to a plurality of conductive terminals 74 via lead frame (not specifically shown), such that the conductive terminals 74 are positioned about the die pad 72.

In addition, method 300 of FIG. 10 includes coupling a circuit on the semiconductor die to a plurality of conductive terminals at block 304. For instance, as shown in FIG. 9C, the circuit 20 is coupled (e.g., electrically coupled) to the conductive terminals 74 via a plurality of wire bonds 76. Thus, electrical signals that are routed to and from circuit 20 may be routed through conductive terminals 74 during operations.

Further, method 300 of FIG. 10 includes covering the semiconductor die with a mold compound at block 306. For instance, as shown in FIG. 9D, a mold compound 78 may cover semiconductor die 50, wire bonds 76, and portions of the die pad 72 and conductive terminals 74. Together, the mold compound 78, semiconductor die 50, wire bonds 76, die pad 72, and conductive terminals 74 may form a semiconductor package 80. The uncovered portions of die pad 72 and conductive terminals 74 (that is, the portions of die pad 72 and conductive terminals 74 that are exposed out of mold compound 78) may be coupled to suitable pads or surfaces on another device, such as a printed circuit board (PCB) (not shown) to conductive electrical current and/or heat during operations. The mold compound 78 may comprise a dielectric material that is configured to shield components of the semiconductor package 80 (e.g., semiconductor die 50, wire bonds 76, and portions of die pad 72 and conductive terminals 74) from the dust, dirt, moisture, contaminants, light, or other elements of the outer environment.

The semiconductor package 80 shown in FIG. 9D may comprise a so-called quad flat no-lead (QFN) semiconductor package. In some examples, the semiconductor package 80 may also comprise a different kind or type of semiconductor package, such as, for instance, a gull-wing lead semiconductor package.

The examples disclosed herein include methods for singulating a semiconductor wafer that balance internal stresses of the wafer and thereby increase an accuracy for cut lines formed therein. Accordingly, any cracks that propagate from the cut lines within the wafer may not meander. In addition, in some examples described herein, the parameters of the cutting implement (e.g., laser cutter 40, laser 42) may also be adjusted to reduce or even prevent crack propagation within the wafer during the above-described process, which further reduces the risks of crack meandering. Therefore, using the methods disclosed herein, manufacturing defects resulting from singulation of semiconductor dies may be reduced.

The term “couple” is used throughout the specification. The term may cover connections, communications, or signal paths that enable a functional relationship consistent with this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Unless otherwise stated, “about,” “approximately,” or “substantially” preceding a value means +/−10 percent of the stated value. Modifications are possible in the described examples, and other examples are possible within the scope of the claims.

What is claimed is:

1. A method of manufacturing a semiconductor package, comprising:
forming a plurality of first cuts in a semiconductor wafer, wherein the plurality of first cuts extend through a first portion of a thickness of the semiconductor wafer, and wherein the plurality of first cuts comprises:
a first set of first cuts that are parallel to one another; and
a second set of first cuts that are parallel to one another and perpendicular to the first set of first cuts; and
forming a plurality of second cuts in the semiconductor wafer after forming the plurality of first cuts, wherein the plurality of second cuts are vertically aligned with the plurality of first cuts and extend through a second portion of the thickness of the semiconductor wafer, and wherein the plurality of second cuts comprises:
a first set of second cuts that are parallel to one another; and
a second set of second cuts that are parallel to one another and perpendicular to the first set of second cuts.

2. The method of claim 1, wherein the first portion comprises a first half of the thickness of the semiconductor wafer and the second portion comprises a second half of the thickness of the semiconductor wafer.

3. The method of claim 1, wherein forming the plurality of first cuts comprises forming the plurality of first cuts with a laser cutter,
wherein forming the plurality of second cuts comprises forming the plurality of second cuts with the laser cutter; and
wherein the method further comprises:
forming a first layer of discontinuities in the semiconductor wafer with the laser cutter when forming the plurality of first cuts; and
forming a second layer of discontinuities in the semiconductor wafer with the laser cutter when forming the plurality of second cuts,
wherein the first layer of discontinuities and the second layer of discontinuities are spaced from one another along the thickness of the semiconductor wafer.

4. The method of claim 3, comprising applying an output power level for the laser cutter of 0.5 watts (W) to 0.7 W during forming the plurality of first cuts and forming the plurality of second cuts.

5. The method of claim 4, wherein the semiconductor wafer comprises a device side having a plurality of circuits formed thereon, and a non-device side opposite the device side, and wherein the first portion of the thickness extends from the device side and the second portion of the thickness extends from the non-device side.

6. The method of claim 5, comprising directing a laser of the laser cutter through the non-device side while forming the plurality of first cuts and forming the plurality of second cuts.

7. The method of claim 5, comprising directing a laser of the laser cutter through the device side while forming the plurality of first cuts and forming the plurality of second cuts.

8. A method of manufacturing a semiconductor package, comprising:
directing a laser into a semiconductor wafer, wherein the semiconductor wafer comprises a plurality of circuits and a plurality of scribe streets positioned between the circuits;
forming a plurality of first cuts with the laser through a first portion of a thickness of the semiconductor wafer that are vertically aligned with the scribe streets; and
after forming the plurality of first cuts, forming a plurality of second cuts with the laser through a second portion of the thickness of the semiconductor wafer that are vertically aligned with the plurality of first cuts.

9. The method of claim 8, wherein forming the plurality of first cuts and forming the plurality of second cuts comprises applying an output power level for the laser of 0.5 Watts (W) to 0.7 W.

10. The method of claim 9, wherein the semiconductor wafer comprises a device side and a non-device side, wherein the device side comprises the plurality of circuits and the plurality of scribe streets, and wherein the first portion of the thickness extends from the device side and the second portion of the thickness extends from the non-device side.

11. The method of claim 18, wherein forming the plurality of first cuts and forming the plurality of second cuts comprises directing the laser into the semiconductor wafer from the non-device side.

12. The method of claim 10, wherein forming the plurality of first cuts and forming the plurality of second cuts comprises directing the laser into the semiconductor die from the device side.

13. The method of claim 10, wherein forming the plurality of first cuts and forming the plurality of second cuts comprises not cutting tape that is attached to the device side.

14. The method of claim 8, comprising preventing crack propagating from the plurality of first cuts and the plurality of second cuts from meandering outside of the scribe streets.

15. A method of manufacturing a semiconductor package, comprising:
emitting an infrared laser from a laser cutter at a power level between 0.5 Watts (W) and 0.7 W;
forming a plurality of first cuts in a semiconductor wafer with the laser, wherein the plurality of first cuts extend through a first portion of a thickness of the semiconductor wafer; and
forming a plurality of second cuts in the semiconductor wafer with the laser after forming the plurality of first cuts, wherein the plurality of second cuts are aligned with the plurality of first cuts and extend through a second portion of the thickness of the semiconductor wafer.

16. The method of claim 15, wherein the first portion comprises a first half of the thickness of the semiconductor wafer and the second portion comprises a second half of the thickness of the semiconductor wafer.

17. The method of claim 15, wherein the semiconductor wafer comprises a device side having a plurality of circuits formed thereon, and a non-device side opposite the device side, and wherein the first portion of the thickness extends from the device side and the second portion of the thickness extends from the non-device side.

18. The method of claim 17, comprising directing the laser through the non-device side while forming the plurality of first cuts and forming the plurality of second cuts.

19. The method of claim 17, comprising directing the laser through the device side while forming the plurality of first cuts and forming the plurality of second cuts.

20. The method of claim 15, comprising:
separating a semiconductor die from the semiconductor wafer as a result of forming the plurality of first cuts and forming the plurality of second cuts;
coupling a circuit on the semiconductor die to a plurality of conductive terminals; and
covering the semiconductor die with a mold compound.
